(19) United States
(12) Patent Application Publication
(10) Pub. No.: US 2018/0198014 A1
(43) Pub. Date: Jul. 12, 2018

(54) SOLAR CELL MODULE AND METHOD OF MANUFACTURE THEREOF

(71) Applicant: Panasonic Intellectual Property Management Co., Ltd., Osaka (JP)

(72) Inventors: KEI TOYOTA, Osaka (JP); MASATO MORI, Hyogo (JP); SHINNOSUKE AKIYAMA, Osaka (JP)

(21) Appl. No.: 15/846,167

(22) Filed: Dec. 18, 2017

(30) Foreign Application Priority Data
Jan. 11, 2017 (JP) 2017-002768

(51) Int. Cl. H01L 31/055; H01L 31/049; H01L 31/048; H01L 31/05

(52) U.S. Cl. CPC H01L 31/055; H01L 31/0504; H01L 31/0481; H01L 31/049

(57) ABSTRACT

A solar cell module having an extended lifetime and improved efficiency achieved by improved solar cell efficiency, and reduced UV damage to the photoelectric conversion device. The solar cell module has a structure in which a back sheet, a first encapsulant layer, a photoelectric conversion device electrically connected to an electrode, a second encapsulant layer, and a protective glass are stacked in that order. The second encapsulant layer is a sheet configured from a resin containing a UV absorber, and the sheet contains phosphors that are concentrated on the side of the protective glass, as opposed to the side of the first encapsulant layer.

### TECHNICAL FIELD

The technical field relates to a solar cell module, and a method of manufacture thereof.

### BACKGROUND

Solar cell modules typically have low sensitivity in shorter wavelength regions, and fail to make effective use of shorter wavelength light, including the ultraviolet light in sunlight. Phosphor is a substance that absorbs light of shorter wavelength regions and fluoresces light of longer wavelength regions. It has been used as a wavelength conversion material to increase the quantity of longer wavelength light and to improve the output of a solar cell module.

The photoelectric conversion device of a solar cell module deteriorates after prolonged exposure to ultraviolet (UV) light. Thus it is desirable to take measures to remove the UV component from the light that falls on the photoelectric conversion device. For this purpose, a UV absorber is typically used in the front filler of the photoelectric conversion device. Such a UV absorber would not be necessary if ultraviolet light could be sufficiently absorbed with the phosphor alone. However, in many cases, the phosphor cannot absorb sufficient quantities of ultraviolet light by itself, and needs to be used along with a UV absorber.

However, when the phosphor and a UV absorber are contained in the filler protecting the photoelectric conversion device, the light of the UV region that needs to be absorbed by the phosphor becomes absorbed by the UV absorber. This results in the phosphor emitting smaller quantities of light, and it becomes difficult to improve efficiency by wavelength conversion.

As a countermeasure to this problem, for example, a phosphor that absorbs light in a different wavelength region from the light of wavelengths absorbed by a UV absorber is provided in a UV absorber-containing layer to prevent UV damage on the photoelectric conversion device and achieve high efficiency by wavelength conversion (see, for example, JP-A-2011-238639). In another configuration, a UV absorber is contained in an organic resin holding a photoelectric conversion device from both sides, and a phosphor is disposed on the light incident side of a front protective glass. This prevents mixing of the UV absorber and the phosphor (see, for example, JP-A-2012-191068).

In yet another configuration, a phosphor-containing encapsulant layer is disposed on a UV absorber-containing encapsulant layer (see, for example, WO2015/129177). In this configuration, ultraviolet light is first absorbed by the upper, phosphor-containing encapsulant layer, and, after fluorescence, an unabsorbed portion of ultraviolet light is absorbed by the lower, UV absorber layer. With this configuration, the technique is intended to achieve high efficiency with the phosphor, and UV absorption by the UV absorber at the same time.

However, with the configuration of JP-A-2011-238639, the phosphor absorbs the light of longer wavelengths, which is effectively used by the photoelectric conversion device, and a proportional efficiency drop is unavoidable. In the configuration of JP-A-2012-191068, a separately provided phosphor layer constitutes the light incident side of the protective glass. Accordingly, the phosphor layer is directly exposed to the outdoor environment, and the phosphor quickly deteriorates. Studies by the present inventors found that the configuration of WO2015/129177 involves time-dependent diffusion of the UV absorber from the UV absorber-containing layer to the phosphor-containing layer. As a result, the UV absorber migrates to the light incident side around the phosphors. This causes a decrease in the quantity of emitted light from the phosphor, and it becomes difficult to achieve high efficiency.

### SUMMARY

The present disclosure is intended to find a solution to the foregoing problems, and it is an object of the present disclosure to provide a solar cell module with which high output can be achieved through wavelength conversion of shorter wavelength light to longer wavelength light while extending life by removing ultraviolet light. The disclosure is also intended to provide a method for manufacturing the solar cell module.

In an aspect of the disclosure, there is provided a solar cell module of a structure including a back sheet, a first encapsulant layer, a photoelectric conversion device electrically connected to an electrode, a second encapsulant layer, and a protective glass that are stacked in this order,

wherein the second encapsulant layer is a sheet configured from a resin containing a UV absorber, and the sheet contains phosphors that are concentrated on the side of the protective glass, as opposed to the side of the first encapsulant layer, and

wherein the phosphors have a refractive index of larger than 1.49 and smaller than 1.51.

In another aspect of the disclosure, there is provided a method for manufacturing a solar cell module of a structure including a back sheet, a first encapsulant layer, a photoelectric conversion device electrically connected to an electrode, a second encapsulant layer, and a protective glass that are stacked in this order,

the method including:

applying a phosphor to one surface of a sheet configured from a resin containing a UV absorber;

forming the second encapsulant layer by embedding the applied phosphor in the vicinity of the phosphor-applied resin surface;

electrically connecting the photoelectric conversion device and the electrode to each other;

stacking the protective glass, the second encapsulant layer disposed in such an orientation that the surface embedded with the phosphor is on the side of the protective glass, the photoelectric conversion device electrically connected to the electrode, the first encapsulant layer, and the back sheet in this order to form a stacked structure; and

laminating the stacked structure.

In yet another aspect of the disclosure, there is provided a method for manufacturing a solar cell module of a structure including a back sheet, a first encapsulant layer, a photoelectric conversion device electrically connected to an electrode, a second encapsulant layer, and a protective glass that are stacked in this order,

the method including:

applying a phosphor to one surface of a sheet configured from a resin containing a UV absorber;

electrically connecting the photoelectric conversion device and the electrode to each other;

stacking the protective glass, the resin sheet disposed in such an orientation that the phosphor-applied surface is on the side of the protective glass, the photoelectric conversion device electrically connected to the electrode, the first encapsulant layer, and the back sheet in this order to form a stacked structure; and

laminating the stacked structure.

In the configuration of the solar cell module of the aspect of the present disclosure, the second encapsulant layer that is disposed closer to the light incident side than the photoelectric conversion device has a phosphor concentrated region formed by concentrating phosphors in the vicinity of the surface of the UV absorber layer on the side of the protective glass. In this way, the UV absorber does not easily migrate to the protective glass side around the phosphors, and is unlikely to interfere with the absorption of UV light by the phosphors. The UV light absorbing effect of the UV absorber protects the photoelectric conversion device from UV damage. In this way, the high efficiency achieved by wavelength conversion can be maintained for extended time periods in the solar cell module.

### BRIEF DESCRIPTION OF THE DRAWINGS

FIG. 1 is a cross sectional view illustrating a cross sectional structure of a solar cell module of First Embodiment.

FIG. 2A is a cross sectional view schematically illustrating the state in which a back sheet, a first encapsulant layer, photoelectric conversion devices electrically connected to an electrode, a second encapsulant layer, and a protective glass are disposed in this order according to manufacturing method A for the solar cell module of First Embodiment.

FIG. 2B is a cross sectional view showing a cross sectional structure of the solar cell module obtained by using manufacturing method A in First Embodiment.

FIG. 3A is a cross sectional view schematically illustrating the state in which a back sheet, a first encapsulant layer, photoelectric conversion devices electrically connected to an electrode, a UV absorber layer containing a phosphor substantially evenly applied to the surface on the side of a protective glass, and the protective glass are disposed in this order according to manufacturing method B for the solar cell module of First Embodiment.

FIG. 3B is across sectional view illustrating a cross sectional structure of the solar cell module obtained by using manufacturing method B in First Embodiment.

FIG. 4A is an electron micrograph of a phosphor-embedded UV absorber layer, showing a surface embedded with phosphors.

FIG. 4B is an electron micrograph of the phosphor-embedded UV absorber layer, showing the surface opposite the surface embedded with phosphors.

### DESCRIPTION OF EMBODIMENTS

A solar cell module according to a first aspect has a structure including a back sheet, a first encapsulant layer, a photoelectric conversion device electrically connected to an electrode, a second encapsulant layer, and a protective glass that are stacked in this order,

wherein the second encapsulant layer is a sheet configured from a resin containing a UV absorber, and the sheet contains phosphors that are concentrated on the side of the protective glass, as opposed to the side of the first encapsulant layer.

In a second aspect, the solar cell module according to the first aspect may be such that the photoelectric conversion device includes a plurality of photoelectric conversion devices that are electrically connected to each other.

In a third aspect, the solar cell module according to the first or second aspect, the phosphors can include particulate inorganic compound phosphors.

In a fourth aspect, the solar cell module according to the third aspect may be such that the inorganic compound phosphors have an average particle size of 0.03 μm or more and 50 μm or less.

In a fifth aspect, the solar cell module according to any one of the first to the fourth aspect may be such that the UV absorber-containing resin is polyethylene, or an ethylene-vinyl acetate copolymer.

In a sixth aspect, the solar cell module according to any one of the first to the fifth aspect may be such that the second encapsulant layer has a thickness of 0.03 μm or more and 250 μm or less in a region where the phosphors are concentrated.

A method for manufacturing a solar cell module according to a seventh aspect is a method for manufacturing a solar cell module of a structure including a back sheet, a first encapsulant layer, a photoelectric conversion device electrically connected to an electrode, a second encapsulant layer, and a protective glass that are stacked in this order,

the method including:

applying a phosphor to one surface of a sheet configured from a resin containing a UV absorber;

forming the second encapsulant layer by embedding the applied phosphor in the vicinity of the phosphor-applied resin surface;

electrically connecting the photoelectric conversion device and the electrode to each other;

stacking the protective glass, the second encapsulant layer disposed in such an orientation that the surface embedded with the phosphor is on the side of the protective glass, the photoelectric conversion device electrically connected to the electrode, the first encapsulant layer, and the back sheet in this order to form a stacked structure; and

laminating the stacked structure.

A method for manufacturing a solar cell module according to an eighth aspect is a method for manufacturing a solar cell module of a structure including a back sheet, a first encapsulant layer, a photoelectric conversion device electrically connected to an electrode, a second encapsulant layer including a sheet configured from a resin containing a UV absorber, and a protective glass that are stacked in this order,

the method including:

applying a phosphor to one surface of the sheet configured from the UV absorber-containing resin;

electrically connecting the photoelectric conversion device and the electrode to each other;

stacking the protective glass, the sheet disposed in such an orientation that the phosphor-applied surface is on the side of the protective glass, the photoelectric conversion device electrically connected to the electrode, the first encapsulant layer, and the back sheet in this order to form a stacked structure; and

laminating the stacked structure.

A solar cell module according to an embodiment is described below in detail, with reference to the accompanying drawings.

### First Embodiment

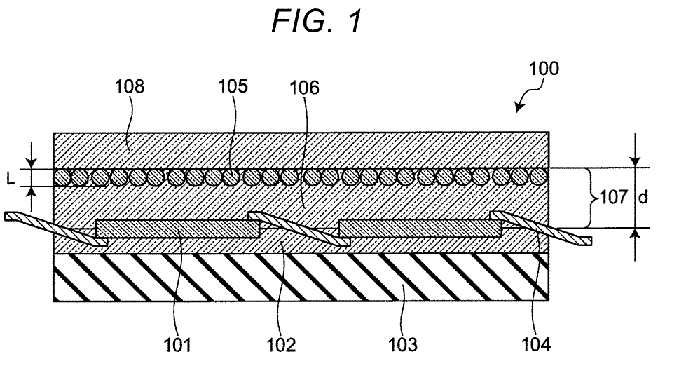

FIG. 1 is a cross sectional view illustrating a cross sectional structure of a solar cell module 100 according to First Embodiment. The solar cell module 100 according to the present First Embodiment includes at least a photoelectric conversion device 101, a first encapsulant layer 102, a back sheet 103, an electrode 104, a second encapsulant layer 107, and a protective glass 108. The solar cell module 100 is structured so that the back sheet 103, the first encapsulant layer 102, the photoelectric conversion device 101, the second encapsulant layer 107, and the protective glass 108 are stacked in this order. The first encapsulant layer 102 is formed of a transparent resin provided on the back of the photoelectric conversion device 101 for protection. The photoelectric conversion device is electrically connected to the electrode 104. The second encapsulant layer 107 is a sheet configured from a resin containing a UV absorber. Specifically, the solar cell module 100 has a structure with a phosphor concentrated region in which the UV absorber layer 106 containing a UV absorber contains phosphors 105 that are concentrated on the side the protective glass 108, or in the vicinity of the light incident side, as opposed to the side of the first encapsulant layer 102.

In this configuration of the solar cell module 100, the phosphor concentrated region is formed in the second encapsulant layer 107 disposed closer to the light incident side than the photoelectric conversion device 101 so that the phosphors 105 are concentrated in the vicinity of the surface of the UV absorber layer 106 on the side of the protective glass 108. In this way, the UV absorber cannot easily migrate around the phosphors 105 toward the protective glass 108. That is, the UV absorber is unlikely to interfere with the absorption of UV light by the phosphors 105. At the same time, the UV absorbing effect of the UV absorber protects the photoelectric conversion device 101 from UV damage. In this way, the solar cell module 100 can maintain wavelength conversion for a long time with high efficiency.

The following describes the constituting members of the solar cell module 100.

### Photoelectric Conversion Device

The photoelectric conversion device 101 may be a silicon semiconductor of, for example, monocrystalline silicon, polycrystalline silicon, or amorphous silicon, or may be a compound semiconductor such as a gallium-arsenic semiconductor, and a cadmium-tellurium semiconductor. The photoelectric conversion device 101 may include a plurality of photoelectric conversion devices that are electrically connected to each other. When using a plurality of photoelectric conversion devices, the photoelectric conversion devices may be connected in series or in parallel.

### Electrode

The photoelectric conversion device 101 is electrically bonded with the electrode 104. The electrode 104 may be a known metallic material or alloy material. The electrode 104 may include a pair of electrodes. The output from the photoelectric conversion device 101 can be obtained through the pair of electrodes 104. When a plurality of photoelectric conversion devices is electrically connected to each other, the photoelectric conversion devices are connected to the pair of electrodes 104 so that the output can be obtained from the photoelectric conversion devices that are connected to each other either in series or in parallel.

### First Encapsulant Layer

The first encapsulant layer 102 provided for protection on the back of the photoelectric conversion device 101 may use materials such as an ethylene-vinyl acetate copolymer, a bisphenol epoxy resin cured product, polyethylene, an acrylic resin, a silicone resin, and a polycarbonate resin, either alone or as a mixture of two or more.

### Back Sheet

The back sheet 103 is a protective member that prevents entry of water and foreign objects from the back of the solar cell module 100. For example, the back sheet 103 may be a polyethylene terephthalate film.

### Protective Glass

The protective glass 108 may be a known translucent, water-impermeable glass plate.

Second Encapsulant layer

The second encapsulant layer 107 has a structure with a phosphor concentrated region in which the UV absorber layer 106 containing a UV absorber contains phosphors 105 that are concentrated on the side of the protective glass 108, or in the vicinity of the surface on the light incident side, as opposed to the side of the first encapsulant layer 102. The second encapsulant layer 107 is an important, essential member of the solar cell module 100 according to the present embodiment, as will be described later in detail.

### UV Absorber Layer

The UV absorber layer 106 is configured from a transparent resin containing a UV absorber. The transparent resin may be, for example, polyvinyl chloride, polyvinylidene chloride, polyvinyl alcohol, polystyrene, a styrene-acrylonitrile copolymer, a styrene-butadiene-acrylonitrile copolymer, polyethylene, an ethylene-vinyl acetate copolymer, polypropylene, polymethyl methacrylate, a methacryl styrene polymer, cellulose acetate, a polycarbonate, a polyester, PET, trivinylidene fluoride, an epoxy resin, a silicone resin, polyethersulfone, a cycloolefin, or triacetate. These may be used alone or as a mixture of two or more. The UV absorber layer 106 may have a thickness of 100 μm to 1,000 μm. When the thickness is less than 100 μm, it is not possible to absorb the UV light that was not absorbed by the phosphors, and UV damage to the photoelectric conversion device 101 cannot be reduced. A thickness thicker than 1,000 μm is not preferable because it leads to increased absorption of light in the visible region by the transparent resin itself, and causes poor conversion efficiency in the photoelectric conversion device 101.

The composition and the type of the UV absorber contained in the transparent resin are not limited. However, the UV absorber may be one having a peak absorption wavelength of 300 nm to 400 nm. When the peak absorption wavelength is less than 300 nm, an unabsorbed portion of UV light through the phosphors cannot be sufficiently absorbed, and the UV damage to the photoelectric conversion device will increase. A peak absorption wavelength of more than 400 nm falls outside of the wavelength region of UV light that passes through the phosphors 105, and it becomes difficult to protect the photoelectric conversion device 101 from UV light. A UV absorber with such a peak absorption wavelength also absorbs the longer wavelength light emitted by the phosphors 105, and becomes an obstacle for improving output through wavelength conversion by the phosphors 105. For transparency, the UV absorber is preferably an organic UV absorber such as a triazine compound, a benzotriazole compound, and a benzophenone compound. The UV absorber may be used alone, or two or more UV absorbers may be used in combination.

Examples of the triazine compound include 2,4-bis(2-hydroxy-4-butoxyphenyl)-6-(2,4-dibutoxyphenyl)-1,3,5-triazine, and 2-[2-hydroxy-4-(1-octyloxycarbonylethoxy)phenyl]-4,6-bis(4-phenylphenyl)-1,3,5-triazine.

Examples of the benzotriazole compound include 2-(3,5-di-t-butyl-2-hydroxyphenyl)benzotriazole, 2-(2H-benzotriazol-2-yl)-4,6-bis(1-methyl-1-phenylethyl)phenol, 2-(2-hydroxy-5-t-butylphenyl)-2H-benzotriazole, 2-(5-methyl-2-hydroxyphenyl)benzotriazole, 2-(2H-benzotriazol-2-yl)-6-(1-methyl-1-phenylethyl)-4-(1,1,3,3-tetramethylbutyl)phenol, 2-(3,5-di-t-butyl-2-hydroxyphenyl)-5-chlorobenzotriazole, 2-(3,5-di-t-amyl-2-hydroxyphenyl)benzotriazole, 2-(3-t-butyl-5-methyl-2-hydroxyphenyl)-5-chlorobenzotriazole, 2-(5-di-t-octyl-2-hydroxyphenyl)benzotriazole, and 2-[3-(2H-benzotriazol-2-yl)-4-hydroxyphenyl]ethyl methacrylate.

Examples of the benzophenone compound include 2,2′-dihydroxy-4-methoxybenzophenone, 2,4-dihydroxybenzophenone, 2-hydroxy-4-n-dodecyloxybenzophenone, 2-hydroxy-4-methoxybenzophenone, and 2-hydroxy-4-n-octoxybenzophenone.

The UV absorber may be contained in an amount that makes the transmittance in an absorption wavelength range of 300 nm to 400 nm less than 5%. For example, in the case of a benzophenone UV absorber, the UV absorber may be 0.05 weight parts to 5 weight parts of the transparent resin.

### Phosphor

The phosphor 105 is a wavelength conversion material that absorbs light of a shorter wavelength region, and fluoresces light of a longer wavelength region. The phosphor 105 is concentrated in the vicinity of the surface of the UV absorber layer 106 to form the phosphor concentrated region. From the viewpoint of reducing a loss by the reflection of incident light on the phosphor surface, the phosphor 105 may be an inorganic compound phosphor (hereinafter, also referred to as “inorganic phosphor”) having a refractive index similar to the refractive index of the UV absorber layer 106, and that does not dissolve in the UV absorber layer 106. When the refractive indices are different, it is preferable to select an inorganic phosphor that causes little scattering of light in the visible wavelength region, and that has an average particle size smaller than 100 nm. From the standpoint of improving output by absorbing light of a shorter wavelength region where the photoelectric conversion device has weak sensitivity characteristics, and emitting fluorescence in a longer wavelength region where the sensitivity characteristics are high, the phosphor 105 used in the present First Embodiment is preferably one that absorbs ultraviolet light of 400 nm or less, and fluoresces wavelengths of light longer than 400 nm. When using two different phosphors, it is preferable to select phosphors so that the fluorescence wavelength of a first phosphor overlaps the absorption wavelength of a second phosphor. In this way, the fluorescence is emitted over a wider wavelength range, and the output improves.

The inorganic phosphors are not particularly limited, and known materials may be used. Typically, for example, oxides, nitride, or sulfides may be used that have had the matrix activated with metallic luminescent ions. As an example of such inorganic phosphors, one or more elements such as B, Gd, O, S, Al, Ga, Ba, Sr, K, V, La, Cl, P, In, Zn, Y, Ca, and Mg are used to make up the composition of the matrix, and activated with one or more emission center elements such as Zn, Ho, Tb, Nd, Ag, Mn, Ce, Eu, Dy, and Tm. When using inorganic phosphors such as above in the present First Embodiment, the average particle size is desirably 0.03 μm to 0.3 μm. When the average particle size is less than 0.03 μm, the surface defects of inorganic phosphors becomes more problematic, and the emission efficiency decreases. With a particle size of more than 0.3 μm, the light of wavelengths for which the photoelectric conversion device 101 has high sensitivity characteristics becomes lost as the light is scattered by inorganic phosphor particles.

Examples of the inorganic phosphors that are more preferred for use include silica phosphors in which oxides, nitrides, or sulfides containing elements that become luminescent ions are distributed in a silica filler that contains silicon dioxide as a primary component. The primary component of a silica phosphor is silica, specifically silicon dioxide, and the refractive index is larger than 1.49, and smaller than 1.51. This is preferable because the refractive index becomes close to the refractive index of the UV absorber layer 106 or the second encapsulant layer 107, and makes it easier to improve transparency when the filler resin forming the matrix of the UV absorber layer 106 is an ethylene-vinyl acetate copolymer or polyethylene. When using a silica phosphor, the silica phosphor may be one having an average particle size of 0.05 μm to 50 μm. When the average particle size is smaller than 0.05 μm, the phosphor particles easily aggregate, and air becomes trapped between particles when they aggregate. This causes the second encapsulant layer 107 to lose transparency, and it becomes difficult to improve efficiency. The extent of light scattering by phosphor particles increases when the average particle size is larger than 50 μm. Further, a large exposure of phosphor particles from the filler surface causes poor adhesion for the protective glass 108 in the assembly process of the solar cell module with the laminate (described later). This causes defects such as detachment between the second encapsulant layer 107 and the protective glass 108.

As another example, the phosphor may be a complex phosphor. The complex phosphor is not particularly limited, and follows the common definition. For example, the complex phosphor is a molecular compound in which at least one ligand is coordinated to at least one central metal atom by coordinate bonding or hydrogen bonding, and in which the central metal atom is the emission center. Whether or not the central metal atom is an ion is not of concern. Examples of the emission center central metal atom include transition metals such as Fe, Cu, Zn, Al, and Au. Lanthanoid elements such as Gd, Yb, Y, Eu, Tb, Yb, Nd, Er, Sm, Dy, and Ce are preferred for their advantages including a large difference between the wavelength of the light it absorbs and the wavelength of emitted light, a small drop in emission efficiency due to fluorescence resorption, and high quantum efficiency.

### Method for Unevenly Distributing Phosphors in UV Absorber Layer

The second encapsulant layer 107 disposed closer to the light incident side than the photoelectric conversion device 101 in the solar cell module 100 of the present First Embodiment forms a phosphor concentrated region where the phosphors 105 are concentrated in the vicinity of the surface of the UV absorber layer 106 on the side of the protective glass 108. In the second encapsulant layer 107, the concentrated region of phosphors 105 may have a thickness L that is equal to or greater than the average particle size of the phosphor particles, and no greater than about 5 times the average particle size of the phosphor particles. From the preferred average particle sizes of the inorganic phosphor and the silica phosphor, the thickness L of the concentrated region of phosphors 105 (phosphor concentrated region) may be 0.05 μm or more and 250 μm or less. When the phosphor concentrated region is formed by concentrating the phosphors in the vicinity of the surface of the second encapsulant layer 107 on the side of the protective glass 108 in the manner described below, the appropriate number of embedding procedures into the surface is about when considering productivity. When the phosphor particles embedded in the nth embedding procedure is pushed inward by the particles embedded in the n+1 embedding procedure, the thickness L of the phosphor concentrated region after five embedding procedures may be at most about 5 times the average particle size of the phosphors.

From the viewpoint of reducing the reflection and refraction of incident light by the phosphors 105, it is preferable that the refractive index difference between the phosphors 105 and the second encapsulant layer 107 is small. Specifically, when the refractive index of the phosphors 105 is n₁, and the refractive index of the second encapsulant layer 107 is n₂, the refractive index difference is preferably −0.1≤n₁−n₂≤0.1.

The thickness d of the second encapsulant layer 107 corresponds to the thickness d of the UV absorber layer 106 embedded with phosphors 105 in the solar cell module 100, as shown in FIG. 1. The thickness of the phosphor concentrated region L is confined within the thickness d of the second encapsulant layer 107.

### Solar Cell Module Manufacturing Method

A process for manufacturing the solar cell module 100 of First Embodiment is described below.

(1) First, the UV absorber layer 106, one of the constituting elements of the second encapsulant layer 107, is produced. A UV absorber is dissolved or dispersed by a known method of mixing and kneading a UV absorber in a hot molten transparent resin, and the kneaded resin is formed into a sheet shape by roll drawing or heat press to produce the UV absorber layer 106. For example, 1 g of benzophenone UV absorber 2,4-dihydroxybenzophenone is added to 200 g of an ethylene-vinyl acetate copolymer, and mixed at 100 rpm for about 30 minutes in a planetary mixer that has been heated to 120° C. The mixture is then pressed with a heat press that has been heated to 120° C., after adjusting the gap with a stainless steel spacer having a certain thickness. This is followed by cooling to obtain the UV absorber layer 106.

(2) Thereafter, particles of phosphors 105 are prepared, and concentrated in the vicinity of one surface of the UV absorber layer 106 to form the phosphor concentrated region, in the manner described below. Specifically, an appropriate amount of phosphor 105 particles is applied to a surface of the UV absorber layer 106, and substantially evenly distributed using, for example, an edge of a spatula-like plate, a squeegee, or a brush. Here, the particles can stably adhere to the surface of the UV absorber layer 106 by electrostatic attraction or physical adsorption. Once adhered, the particles can stably remain on the surface of the UV absorber layer 106. With the particles of phosphors 105 evenly adhering and held to the surface, the UV absorber layer 106 is heat pressed while maintaining a certain gap with a spacer or the like. In this way, the particles of phosphors 105 adhering to the surface can be embedded in the vicinity of the surface of the UV absorber layer 106. Here, the particles of phosphors 105 are concentrated in the vicinity of the surface of the UV absorber layer 106, and the second encapsulant layer 107 is formed that has a structure with the phosphor concentrated region. Considering that the phosphors 105 are embedded in the vicinity of the surface of the UV absorber layer 106 under applied heat, the method is not limited to the heat press, and a heat roll technique may also be used.

### Manufacturing Method A

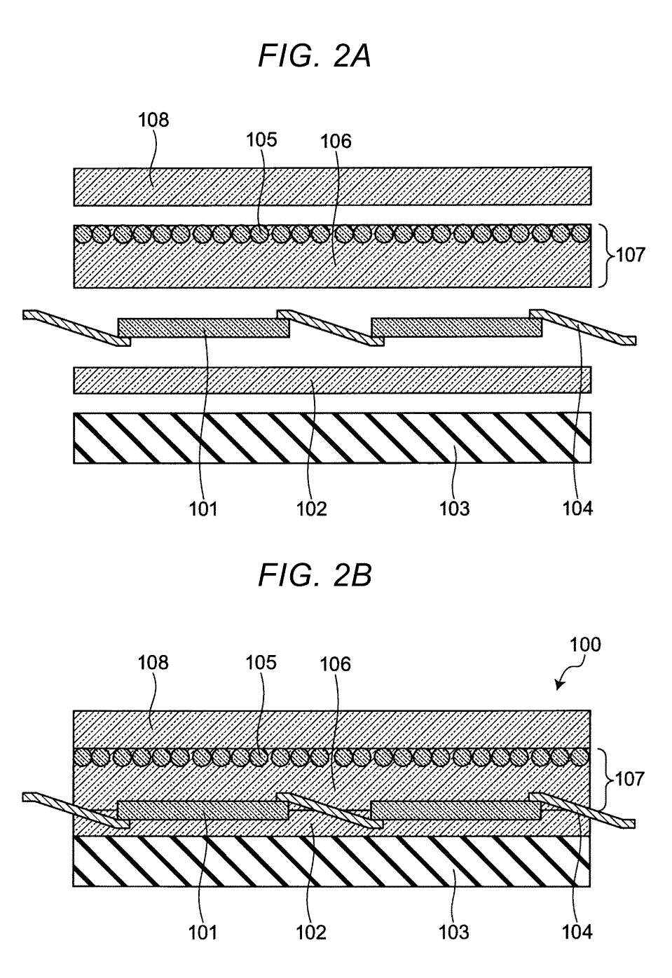

The following describes manufacturing method A, in which the UV absorber layer 106 having the phosphor concentrated region with the unevenly distributed phosphors 105, specifically, the second encapsulant layer 107 is laminated with other members. FIG. 2A is a cross sectional view schematically illustrating the state in which the back sheet 103, the first encapsulant layer 102, the photoelectric conversion devices 101 electrically connected to the electrode 104, the second encapsulant layer 107 produced in the manner described above, and the protective glass 108 are disposed in this order according to manufacturing method A. FIG. 2B is a cross sectional view showing a cross sectional structure of the solar cell module 100 obtained by using manufacturing method A.

The back sheet 103, the first encapsulant layer 102, the photoelectric conversion devices 101 electrically connected to each other with the electrode 104, the second encapsulant layer 107 produced in the manner described above, and the protective glass 108 are stacked in this order to obtain a stacked structure, and these are subjected to a lamination process to produce the solar cell module 100. In this way, the UV absorber in the UV absorber layer 106 can absorb the unabsorbed ultraviolet light through the phosphors 105 while the phosphors 105 convert ultraviolet light into longer wavelength light, and improve the output. This makes it possible to improve the output and the lifetime of the solar cell module 100 with the photoelectric conversion device 101 protected from UV damage. Here, the second encapsulant layer 107 needs to be disposed in such an orientation that the surface with the concentrated phosphors is on the side of the protective glass 108. Specifically, the solar cell module 100 of the present First Embodiment can be manufactured by using a silver-plated copper wire as the electrode 104, a monocrystalline silicon photoelectric conversion device as the photoelectric conversion device 101, and an ethylene-vinyl acetate copolymer as the first encapsulant layer 102 of the photoelectric conversion device 101.

With the manufacturing method A, the presence or absence of nontransparent portions due to, for example, aggregation of phosphors 105 in the second encapsulant layer 107 can be checked with the naked eye, and the solar cell module 100 can be manufactured after selecting products with no such nontransparent portions in the production of the second encapsulant layer 107 containing phosphors 105 that are concentrated on one side of the UV absorber layer 106. This makes it possible to improve the yield of the solar cell module, and reduce manufacturing cost.

Manufacturing method A is a method in which the second encapsulant layer 107 is prepared before being laminated with other members in a lamination process. The method therefore enables the phosphors 105 to be repeatedly embedded into a surface of the UV absorber layer 106. That is, the process of applying the phosphors 105 to the UV absorber layer 106, and embedding the phosphors 105 in the UV absorber layer 106 by heat press or other techniques can be repeated multiple times to form a phosphor concentrated region containing larger numbers of phosphors 105. In this way, the quantity of emitted light can increase, and the solar cell module 100 can have improved efficiency by wavelength conversion.

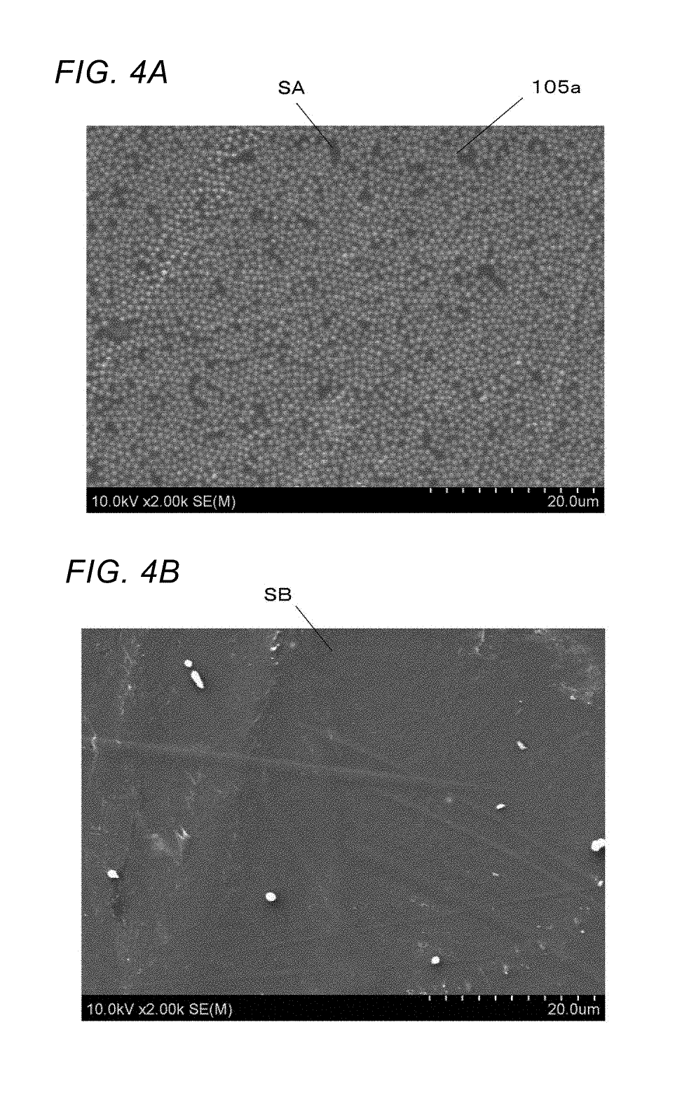

FIG. 4A shows an example of an electron micrograph of a surface SA embedded with phosphors 105a in the UV absorber layer 106 embedded with phosphors 105. FIG. 4B shows an electron micrograph of a surface SB opposite the surface embedded with the phosphors 105.

Here, the phosphor is a silica phosphor 105a formed after a fine phosphor particle having an Eu²⁺ emission center is embedded in the porous portion of a porous silica filler, and sintered. The silica phosphor 105a has a particle size of 1.0 μm. For the production of the UV absorber layer, 1 g of benzophenone UV absorber 2,4-dihydroxybenzophenone was added to 200 g of a low-density polyethylene resin, and mixed at 100 rpm for about 30 minutes in a planetary mixer that had been heated to 150° C. The mixture was then pressed with a heat press that had been heated to 150° C., after adjusting the gap with a 550-μm stainless steel spacer. This was followed by cooling to obtain the UV absorber layer.

Thereafter, the silica phosphors 105a were applied to one surface of the UV absorber layer 106 in an amount of about 300 μg per 1 cm², using a brush, and the UV absorber layer with the silica phosphors applied to one surface was pressed with a heat press that had been heated to 150° C., after adjusting the gap with a 550-μm stainless steel spacer. This was followed by cooling to embed the applied silica phosphors 105a in the vicinity of the surface of the UV absorber layer 106, and concentrate the phosphors 105 in the vicinity of the surface.

As can be seen in FIGS. 4A and 4B, a high density of phosphors 105a is distributed in the surface embedded with the phosphors 105, whereas the phosphors are absent on the back surface.

### Manufacturing Method B

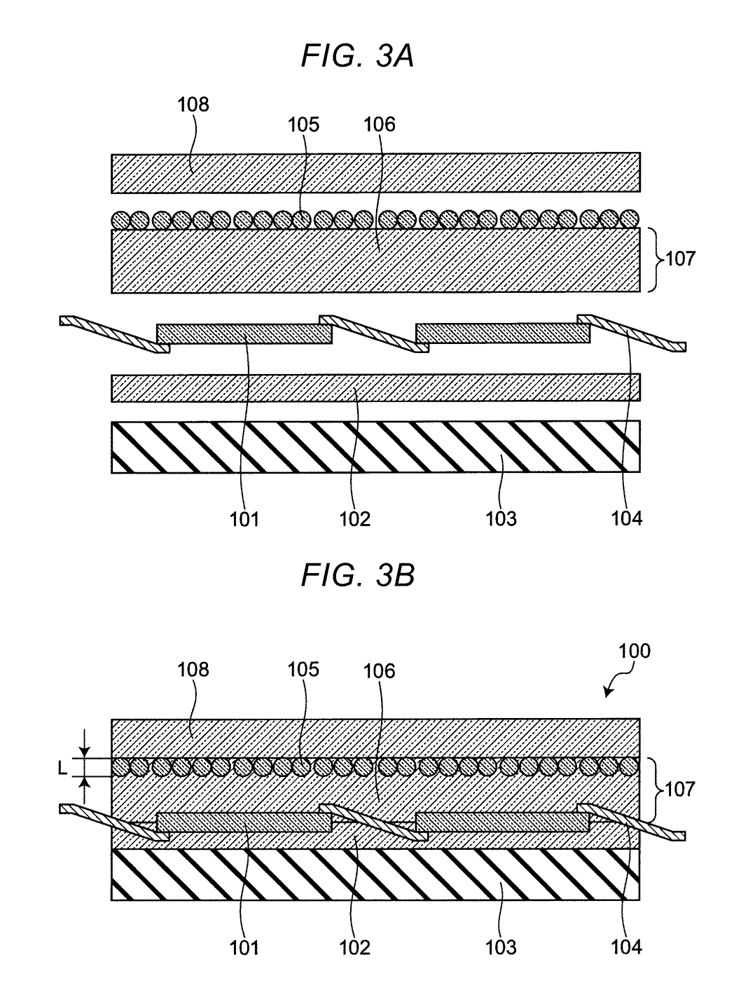

The following describes manufacturing method B in which the phosphors 105 and the UV absorber layer 106 are laminated with the other members. FIG. 3A is a cross sectional view schematically illustrating the state in which the back sheet 103, the first encapsulant layer 102, the photoelectric conversion devices 101 electrically connected to the electrode 104, the UV absorber layer 106 containing phosphors 105 substantially evenly applied to the surface on the side of the protective glass 108, and the protective glass 108 are disposed in this order. FIG. 3B is a cross sectional view illustrating a cross sectional structure of the solar cell module 100 obtained by using manufacturing method B.

The solar cell module 100 of the present embodiment also can be manufactured when the back sheet 103, the first encapsulant layer 102, the photoelectric conversion devices 101 electrically connected to the electrode 104, the UV absorber layer 106 containing phosphors 105 substantially evenly applied to the surface on the side of the protective glass 108 in the manner described above, and the protective glass 108 are stacked in this order, and subjected to a lamination process without having to prepare the second encapsulant layer 107 with the phosphors 105 and the UV absorber layer 106 in advance.

With the manufacturing method B, the second encapsulant layer 107 having the phosphor concentrated region in which the phosphors 105 are concentrated in the vicinity of one surface the UV absorber layer 106 can be formed at the time of manufacturing the solar cell module 100. This should improve productivity.

The following describes Examples and Comparative Examples in detail.

Tables 1 and 2 show the compositions of the phosphor 105 and the UV absorber layer 106, and the manufacturing methods used in Examples, and the compositions of Comparative Examples, along with the evaluation results, which will be described later.

TABLE 1

| | | Ex. 1 | Ex. 2 | Ex. 3 |
|---|---|---|---|---|
| Phosphor | Phosphor | Silica phosphor | Silica phosphor | Silica phosphor |
| concentrated | Average particle size | 1.0 | 50 | 0.05 |
| region | (μm) | | | |
| | Thickness of phosphor | 1.0 | 50 | 0.05 |
| | concentrated region | | | |
| | (μm) | | | |
| | Number of phosphor | 1 | 1 | 1 |
| | concentrated region- | | | |
| | forming processes | | | |
| UV absorber | UV absorber | 2,4-Dihydroxybenzophenone | 2,4-Dihydroxybenzophenone | 2,5-Dihydroxybenzophenone |
| layer | Resin | Low-density polyethylene | Low-density polyethylene | Low-density polyethylene |
| | Content (weight parts) | 0.5 | 0.5 | 0.5 |
| | Thickness (μm) | 550 | 550 | 550 |

| Manufacturing method | A | | A | | A | |
|---|---|---|---|---|---|---|
| Transmittance at 370 nm (%) | 0.7 | Good | 0.7 | Good | 0.7 | Good |
| Output value relative to Comparative | 0.4 | Good | 0.3 | Good | 0.2 | Good |
| Example 1 at 100 | | | | | | |
| Percentage of retained output value | 98 | Good | 98 | Good | 98 | Good |
| after 240 hours of continuous UV | | | | | | |
| irradiation at 100 mW/cm² | | | | | | |

| Overall Evaluation | | Good | Good | Good |
|---|---|---|---|---|
| | | Ex. 4 | Ex. 5 | Ex. 6 |
| Phosphor | Phosphor | Silica phosphor | Silica phosphor | Mn-containing zinc silicate |
| concentrated | Average particle size | 50 | 1.0 | 0.05 |
| region | (μm) | | | |
| | Thickness of phosphor | 250 | 1.0 | 0.05 |
| | concentrated region | | | |
| | (μm) | | | |
| | Number of phosphor | 5 | 1 | 1 |
| | concentrated region- | | | |
| | forming processes | | | |
| UV absorber | UV absorber | 2,6-Dihydroxybenzophenone | 2,4-Dihydroxybenzophenone | 2,4-Dihydroxybenzophenone |
| layer | Resin | Low-density polyethylene | Low-density polyethylene | Ethylene-vinyl acetate |
| | | | | copolymer |
| | Content (weight parts) | 0.5 | 0.5 | 0.5 |
| | Thickness (μm) | 1000 | 550 | 550 |

| Manufacturing method | A | | B | | A | |
|---|---|---|---|---|---|---|
| Transmittance at 370 nm (%) | 0.3 | Excellent | 0.7 | Good | 0.7 | Good |
| Output value relative to Comparative | 0.2 | Good | 0.4 | Good | 0.1 | Good |
| Example 1 at 100 | | | | | | |
| Percentage of retained output value | 99 | Excellent | 98 | Good | 98 | Good |
| after 240 hours of continuous UV | | | | | | |
| irradiation at 100 mW/cm² | | | | | | |

| | | | |
|---|---|---|---|
| Overall Evaluation | Excellent | Good | Good |

| | | Ex .7 | Ex. 8 |
|---|---|---|---|
| Phosphor | Phosphor | Mn-containing zinc silicate | Mn-containing zinc silicate |
| concentrated | Average particle size | 0.03 | 0.30 |
| region | (μm) | | |
| | Thickness of phosphor | 0.03 | 0.3 |
| | concentrated region | | |
| | (μm) | | |
| | Number of phosphor | 1 | 1 |
| | concentrated region- | | |
| | forming processes | | |
| UV absorber | UV absorber | 2,4-Dihydroxybenzophenone | 2,4-Dihydroxybenzophenone |
| layer | Resin | Ethylene-vinyl acetate | Ethylene-vinyl acetate |
| | | copolymer | copolymer |
| | Content (weight parts) | 0.5 | 0.5 |
| | Thickness (μm) | 550 | 550 |

| Manufacturing method | A | | A | |
|---|---|---|---|---|
| Transmittance at 370 nm (%) | 0.7 | Good | 0.7 | Good |
| Output value relative to Comparative | 0.1 | Good | 0.1 | Good |
| Example 1 at 100 | | | | |
| Percentage of retained output value | 98 | Good | 98 | Good |
| after 240 hours of continuous UV | | | | |
| irradiation at 100 mW/cm² | | | | |

| | | |
|---|---|---|
| Overall Evaluation | Good | Good |

TABLE 2

| | | Com. Ex. 1 | Com. Ex. 2 | Com. Ex. 3 |
|---|---|---|---|---|
| Phosphor | Phosphor | — | Silica phosphor | Silica phosphor |
| concentrated | Average particle size | — | 1.0 | 0.02 |
| region | (μm) | | | |
| | Thickness of phosphor | — | 1.0 | 0.02 |
| | concentrated region | | | |
| | (μm) | | | |
| | Number of phosphor | — | 1 | 1 |
| | concentrated region- | | | |
| | forming processes | | | |
| Phosphor | Phosphor | Silica phosphor | — | — |
| layer | Average particle size | 1.0 | — | — |
| | (μm) | | | |
| | Resin | Low-density polyethylene | — | — |
| | Content (weight parts) | 3 | — | — |
| | Thickness (μm) | 300 | — | — |
| UV absorber | UV absorber | 2,4-Dihydroxybenzophenone | — | 2,4-Dihydroxybenzophenone |
| layer | Resin | Low-density polyethylene | Low-density polyethylene | Low-density polyethylene |

| | | | |
|---|---|---|---|
| Content (weight parts) | 0.5 | — | 0.5 |

| | | | |
|---|---|---|---|
| Thickness (μm) | 300 | 550 | 550 |

| | | | |
|---|---|---|---|
| Manufacturing method | — | A | A |

| | | | | | | |
|---|---|---|---|---|---|---|
| Transmittance at 370 nm (%) | 0.6 | Good | 85 | Poor | 0.7 | Good |
| Output value relative to Comparative | 0 | Poor | 1.1 | Excellent | −0.1 | Poor |
| Example 1 at 100 | | | | | | |
| Percentage of retained output value | 96 | Good | 79 | Poor | 98 | Good |
| after 240 hours of continuous UV | | | | | | |
| irradiation at 100 mW/cm² | | | | | | |

| | | | |
|---|---|---|---|
| Overall Evaluation | Poor | Poor | Poor |

| | | Com. Ex. 4 | Com. Ex. 5 | Com. Ex. 6 |
|---|---|---|---|---|
| Phosphor | Phosphor | Silica phosphor | Silica phosphor | Mn-containing zinc silicate |
| concentrated | Average particle size | 75.0 | 50.0 | 0.01 |
| region | (μm) | | | |
| | Thickness of phosphor | 75.0 | 350.0 | 0.01 |
| | concentrated region | | | |
| | (μm) | | | |
| | Number of phosphor | 1 | 7 | 1 |
| | concentrated region- | | | |
| | forming processes | | | |
| Phosphor | Phosphor | — | — | — |
| layer | Average particle size | — | — | — |
| | (μm) | | | |
| | Resin | — | — | — |
| | Content (weight parts) | — | — | — |
| | Thickness (μm) | — | — | — |
| UV absorber | UV absorber | 2,4-Dihydroxybenzophenone | 2,4-Dihydroxybenzophenone | 2,4-Dihydroxybenzophenone |
| layer | Resin | Low-density polyethylene | Low-density polyethylene | Ethylene-vinyl acetate |
| | | | | copolymer |
| | Content (weight parts) | 0.5 | 0.5 | 0.5 |
| | Thickness (μm) | 550 | 1000 | 550 |

| Manufacturing method | A | | A | | A | |
|---|---|---|---|---|---|---|
| Transmittance at 370 nm (%) | 0.7 | Good | 0.35 | Excellent | 0.8 | Good |
| Output value relative to Comparative | −0.2 | Poor | −0.2 | Poor | −0.2 | Poor |
| Example 1 at 100 | | | | | | |
| Percentage of retained output value | 98 | Good | 99 | Excellent | 98 | Good |
| after 240 hours of continuous UV | | | | | | |
| irradiation at 100 mW/cm² | | | | | | |

| | | | |
|---|---|---|---|
| Overall Evaluation | Poor | Poor | Poor |

### Example 1

Example 1 represents an example in which a solar cell module for evaluation was produced according manufacturing method A. As the phosphor, a silica phosphor that had been formed by sintering was used after fine phosphor particles having an Eu²⁺ emission center were embedded in porous portions of a porous silica filler. The silica phosphor had an average particle size of 1.0 μm. For the production of the UV absorber layer, 1 g of benzophenone UV absorber 2,4-dihydroxybenzophenone was added to 200 g of a low-density polyethylene resin, and mixed at 100 rpm for about 30 minutes in a planetary mixer that had been heated to 150° C. The mixture was then pressed with a heat press that had been heated to 150° C., after adjusting the gap with a 550-μm stainless steel spacer. This was followed by cooling to obtain the UV absorber layer. Thereafter, the silica phosphor was applied to one surface of the UV absorber layer in an amount of about 300 μg per 1 cm², using a brush, and the UV absorber layer with the silica phosphor applied to one surface was pressed with a heat press that had been heated to 150° C., after adjusting the gap with a 550-μm stainless steel spacer. This was followed by cooling to embed the applied silica phosphor in the vicinity of the surface of the UV absorber layer, and obtain the second encapsulant layer of the present Example. The second encapsulant layer was measured for transmittance at 370 nm. Separately, another second encapsulant layer was produced in the same configuration, and the thickness of the phosphor concentrated region was measured by observing a cross section with a SEM. The protective glass, the second encapsulant layer having the phosphor concentrated region on the protective glass side, the photoelectric conversion devices connected to each other with an electrode, the first encapsulant layer, and the back sheet were stacked in this order to obtain an evaluation module.

### Examples 2 to 8

Example 2 is the same as Example 1, except that the silica phosphor had an average particle size of 50 μm, and the phosphor concentrated region had a thickness of 50 μm.

Example 3 is the same as Example 1, except that the silica phosphor had an average particle size of 0.05 μm, and the phosphor concentrated region had a thickness of 0.05 μm.

Example 4 is the same as Example 1, except that the silica phosphor had an average particle size of 50 μm, the phosphor was repeatedly applied and embedded in the UV absorber layer 5 times, the phosphor concentrated region had a thickness of 250 μm, and the UV absorber layer had a thickness of 1,000 μm.

Example 5 is the same as Example 1, except that manufacturing method B was used. The method did not allow for measurement of transmittance at 370 nm. However, the measured value of Example 1 was used because the configuration was the same.

Example 6 is the same as Example 1, except that the phosphor is an inorganic phosphor, specifically ZnSiO₄:Mn having an average particle size of 0.05 μm (hereinafter, referred to as “manganese-containing zinc silicate), and that an ethylene-vinyl acetate copolymer was used as the transparent material of the UV absorber layer.

Example 7 is the same as Example 6, except that the inorganic phosphor manganese-containing zinc silicate had an average particle size of 0.03 μm.

Example 8 is the same as Example 6, except that the inorganic phosphor manganese-containing zinc silicate had an average particle size of 0.3 μm.

### Comparative Example 1

In Comparative Example 1, an evaluation module was produced using a phosphor layer that had been prepared as a sheet in which the phosphor was dispersed in a transparent resin, instead of being concentrated in the vicinity of the surface of the UV absorber layer, and by stacking and laminating the back sheet, the first encapsulant layer, the photoelectric conversion devices connected to each other with an electrode, the phosphor layer, and the protective glass in that order. The phosphor layer was produced as follows. First, 3 parts by weight of a silica phosphor was mixed into 200 g of a hot molten low-density polyethylene, and the mixture was kneaded at 100 rpm for about 30 minutes in a planetary mixer that had been heated to 150° C. Thereafter, 30 g of the kneaded product was pressed with a heat press that had been heated to 150° C., after adjusting the gap with a 300-μm stainless steel spacer. This was followed by cooling to obtain the phosphor layer of Comparative Example 1.

The UV absorber layer was produced in a thickness of 300 μm in the same manner as in Example 1, except that a 300 μm-thick spacer was used for the heat press. The phosphor layer and the UV absorber layer were laminated with a heat press, and the transmittance at 370 nm was measured. The evaluation module was then produced by stacking and laminating the back sheet, the first encapsulant layer, the photoelectric conversion devices connected to each other with an electrode, the laminate of the UV absorber layer and the phosphor layer, and the protective glass, in this order. The laminate of the UV absorber layer and the phosphor layers was disposed in such an orientation that the phosphor layer was on the side of the protective glass.

### Comparative Examples 2 to 6

Comparative Example 2 differs from Example 1 in that the layer with the unevenly distributed silica phosphor is a polyethylene layer that does not contain the UV absorber layer 106. Other conditions, including the configuration, and the manufacturing method are the same as in Example 1.

Comparative Example 3 is the same as Example 1, except that the silica phosphor had an average particle size of 0.02 μm, and the phosphor concentrated region had a thickness of 0.02 μm.

Comparative Example 4 is the same as Example 1, except that the silica phosphor had an average particle size of 75 μm.

Comparative Example 5 is the same as Example 4, except that the phosphor was repeatedly applied and embedded in the UV absorber layer 7 times, the phosphor concentrated layer had a thickness of 350 μm, and the UV absorber layer had a thickness of 1,000 μm.

Comparative Example 6 is the same as Example 6, except that the inorganic phosphor manganese-containing zinc silicate had an average particle size of 0.01 μm.

The evaluation modules were measured for conversion efficiency. A rate of output change was also measured by applying ultraviolet light of 100 mW/cm² intensity for 240 hours using a UV irradiator.

These were evaluated under the following criteria.

### Transmittance

The film was measured for transmittance at 370-nm UV light with respect to the baseline measured for reference air.

### Evaluation Criteria

Transmittance of less than 0.5%: Excellent UV blocking effect (Excellent)

Transmittance of 0.5% or more and less than 5%: Desirable UV blocking effect (Good)

Transmittance of 5% or more: Poor UV blocking effect (Poor)

### Output Value

The output of each solar cell module under the light of a Xe lamp was determined using a solar simulator, and a relative value with respect to the output value, 100, of Comparative Example 1 was determined.

### Evaluation Criteria

Output value of 0.5 or more: Excellent output improvement (Excellent)

Output value of more than 0 and less than 0.5: Desirable output improvement (Good)

Output value of 0 or less: No output improvement (Poor)

Percentage of Retained Output Value after Continuous UV Irradiation at 100 mW/Cm² for 240 Hours

Ultraviolet light was continuously applied for 240 hours at 100 mW/cm². The ratio of the output value after irradiation with respect to the output value before irradiation was determined as a percentage of retained output.

### Evaluation Criteria

Percentage of 99% or more: Excellent reduction of UV damage (Excellent)

Percentage of 95% or more and less than 99%: Desirable reduction of UV damage (Good)

Percentage of less than 95%: Insufficient reduction of UV damage (Poor)

### Overall Evaluation

Examples and Comparative Examples that had at least one Poor score were determined as Poor, two or more Excellent scores with no Poor score were determined as Excellent in the overall evaluation of transmittance, output value, and percentage of retained output after UV irradiation. Examples and Comparative Examples that were neither Excellent nor Poor in the overall evaluation were determined as Good.

The following information can be derived from the results presented in Tables 1 and 2.

By comparing Example 1 with Comparative Examples 1 and 2, it can be seen that the solar cell module having the configuration of the embodiment of the present disclosure is a solar cell module having reduced levels of deterioration due to ultraviolet light, and improved conversion efficiency.

By comparing Examples 3 and 4 with Comparative Examples 3 and 5, it can be seen that high conversion efficiency can be obtained when the phosphor concentrated region has a thickness of 0.05 μm or more and 250 μm or less.

By comparing Examples 1, 2, 3, 6, 7, and 8 with Comparative Examples 3, 4, and 6, it can be seen that high conversion efficiency can be obtained when the inorganic compound phosphors have an average particle size of 0.03 μm or more and 50 μm or less.

By comparing Example 1 and Example 5, it can be seen that the solar cell modules produced by using manufacturing method A and manufacturing method B have reduced levels of deterioration due to ultraviolet light, and improved conversion efficiency.

As described above, in the solar cell module according to an embodiment of the present disclosure, light that cannot be effectively used by the photoelectric conversion device is converted into effective wavelengths by the phosphor, and UV damage to the photoelectric conversion device is reduced. In this way, the solar cell module can have improved photoelectric conversion efficiency, and a longer lifespan.

What is claimed is:

1. A solar cell module of a structure comprising a back sheet, a first encapsulant layer, a photoelectric conversion device electrically connected to an electrode, a second encapsulant layer, and a protective glass that are stacked in this order,
wherein the second encapsulant layer is a sheet configured from a resin containing a UV absorber, and the sheet contains phosphors that are concentrated on the side of the protective glass, as opposed to the side of the first encapsulant layer, and
wherein the phosphors have a refractive index of larger than 1.49 and smaller than 1.51.

2. The solar cell module according to claim 1, wherein the photoelectric conversion device includes a plurality of photoelectric conversion devices that are electrically connected to each other.

3. The solar cell module according to claim 1, wherein the phosphors are particulate inorganic compound phosphors.

4. The solar cell module according to claim 3, wherein the inorganic compound phosphors have an average particle size of 0.03 μm or more and 50 μm or less.

5. The solar cell module according to claim 1, wherein the resin containing the UV absorber is polyethylene, or an ethylene-vinyl acetate copolymer.

6. The solar cell module according to claim 1, wherein the second encapsulant layer has a thickness of 0.03 μm or more and 250 μm or less in a region where the phosphors are concentrated.

7. A method for manufacturing a solar cell module of a structure including a back sheet, a first encapsulant layer, a photoelectric conversion device electrically connected to an electrode, a second encapsulant layer, and a protective glass that are stacked in this order,
the method comprising:
applying a phosphor to one surface of a sheet configured from a resin containing a UV absorber;
forming the second encapsulant layer by embedding the applied phosphor in the vicinity of the phosphor-applied resin surface;
electrically connecting the photoelectric conversion device and the electrode to each other;
stacking the protective glass, the second encapsulant layer disposed in such an orientation that the surface embedded with the phosphor is on the side of the protective glass, the photoelectric conversion device electrically connected to the electrode, the first encapsulant layer, and the back sheet in this order to form a stacked structure; and
laminating the stacked structure.

8. A method for manufacturing a solar cell module of a structure including a back sheet, a first encapsulant layer, a photoelectric conversion device electrically connected to an electrode, a second encapsulant layer including a sheet configured from a resin containing a UV absorber, and a protective glass that are stacked in this order,
the method comprising:
applying a phosphor to one surface of the sheet configured from the resin containing the UV absorber;
electrically connecting the photoelectric conversion device and the electrode to each other;
stacking the protective glass, the sheet disposed in such an orientation that the phosphor-applied surface is on the side of the protective glass, the photoelectric conversion device electrically connected to the electrode, the first encapsulant layer, and the back sheet in this order to form a stacked structure; and
laminating the stacked structure.

9. The solar cell module according to claim 1, wherein the resin containing the UV absorber is one or more of the following polyvinyl chloride, polyvinylidene chloride, polyvinyl alcohol, polystyrene, a styrene-acrylonitrile copolymer, a styrene-butadiene-acrylonitrile copolymer, polypropylene, polymethyl methacrylate, a methacryl styrene polymer, cellulose acetate, a polycarbonate, a polyester, PET, trivinylidene fluoride, an epoxy resin, a silicone resin, polyethersulfone, a cycloolefin, or triacetate.

10. The solar cell module according to claim 1, wherein the UV absorber is one or more of the following a triazine compound, a benzotriazole compound, a benzophenone compound.

11. The solar cell module according to claim 1, wherein the phosphors are a complex phosphor.
